(19) United States
(12) Patent Application Publication
(10) Pub. No.: US 2024/0250500 A1
(43) Pub. Date: Jul. 25, 2024

(54) MONOLITHIC INTEGRATED MULTI-SEGMENT CASCADE OPTICAL FREQUENCY COMB AND CHIP THEREOF

(71) Applicant: Hainan Normal University, Haikou (CN)

(72) Inventors: Zhongliang Qiao, Haikou (CN); Yi Qu, Haikou (CN); Haoran Wan, Haikou (CN); Wenjun Yu, Haikou (CN); Dengqun Weng, Haikou (CN); Xiaohu Hou, Haikou (CN); Menghao Wu, Haikou (CN); Ke Hu, Haikou (CN); Zhibin Zhao, Haikou (CN); Hao Chen, Haikou (CN); Zaijin Li, Haikou (CN); Lina Zeng, Haikou (CN); Lin Li, Haikou (CN); Guojun Liu, Haikou (CN)

(21) Appl. No.: 18/624,339

(22) Filed: Apr. 2, 2024

Related U.S. Application Data
(63) Continuation of application No. PCT/CN2023/108587, filed on Jul. 21, 2023.

(51) Int. Cl. H01S 5/065; H01S 5/026; H01S 5/10; H01S 5/12; H01S 5/22; H01S 5/343

(52) U.S. Cl. CPC H01S 5/0657; H01S 5/026; H01S 5/1021; H01S 5/1039; H01S 5/12; H01S 5/22; H01S 5/34313; H01S 5/34346

(57) ABSTRACT

A monolithic integrated multi-segment cascade optical frequency comb and its chip are disclosed, which belongs to the technical field of sensing detection, quantum information and optical communication technology. The optical frequency comb includes a first semiconductor passive mode-locking laser, a semiconductor optical amplifier, and a second semiconductor passive mode-locking laser sequentially integrated and connected; the first semiconductor passive mode-locking laser includes a first reverse bias absorption area integrated with an optogalvanic distribution grating and a first gain cavity length extender (coupled multi-ring or multi-disk); the second semiconductor passive mode-locking laser includes a second reverse bias absorption area and a second gain cavity length extender (coupled multi-ring or multi-disk); each structure is connected to each other by electrical isolation grooves. Through the above structure, the present disclosure realizes an optical frequency comb with small size, high efficiency, tunable, fundamental mode, high power, narrow pulse width, wide spectrum and flexible controllability.

### TECHNICAL FIELD

The present disclosure relates to the technical field of sensing detection, quantum information and optical communication technology, and more specifically to a monolithic integrated multi-segment cascade optical frequency comb and its chip.

### BACKGROUND ART

Optical frequency comb (OFC) is abbreviated as optical comb, each “comb tooth” of an OFC is equivalent to a beam of monochrome laser, these monochrome lasers have a very high coherence with each other, the OFC is able to directly convert the light wave to microwave frequency, and by using the ultra-short pulse of the nonlinear advantage, the OFC can be realized in various spectral bands and with different frequency resolutions.

Since the birth of OFC, OFC based on traditional fiber laser, solid-state laser technology and microcavity structure has problems such as large volume, many components, low repetition frequency, susceptibility to external environmental influences and separation of the light source end and the modulation end, which affects the performance of the OFC and limits the application and development of the OFC.

In addition, traditional semiconductor mode-locking lasers require a short cavity length within 1000 μm to achieve a wide wavelength range of OFC. This cavity length results in a very low output power, and the reverse bias area is subjected to a reverse bias voltage, which has a relatively high absorption of light, making it difficult to achieve a wide spectral frequency comb output and even more difficult to achieve high power output.

Therefore, how to reduce the volume of optical frequency comb and ensure the output of optical frequency comb with high power and wide spectral range is an urgent problem for technicians in this field.

### SUMMARY

In view of the above, the present disclosure provides a monolithic integrated multi-segment cascade optical frequency comb and its chip for solving the problem of realizing a small-size, high-efficiency, tunable, fundamental-mode, high-power, narrow-pulse-width, broad-spectrum, flexible and controllable optical frequency comb.

In order to realize the above purpose, the present disclosure adopts the following technical solutions:

Firstly, the present disclosure provides a monolithic integrated multi-segment cascade optical frequency comb, including:
a first semiconductor passive mode-locking laser, a semiconductor optical amplifier, and a second semiconductor passive mode-locking laser;
wherein, the first semiconductor passive mode-locking laser includes a first reverse bias absorption area integrated with a optogalvanic distribution grating and a first gain cavity length extender; the first reverse bias absorption area is connected to one end of the first gain cavity length extender through a first electrical isolation groove, and the other end of the first gain cavity length extender is connected to the semiconductor optical amplifier through a second electrical isolation groove;
the second semiconductor passive mode-locking laser includes a second gain cavity length extender and a second reverse bias absorption area, one end of the second gain cavity length extender is connected to the semiconductor optical amplifier through a third electrical isolation groove, and the other end of the second gain cavity length extender is connected to the second reverse bias absorption area through a fourth electrical isolation groove.

Preferably, an etching depth of the optogalvanic distribution grating is one-hundredth to one-half of a thickness downwards starting from an upper edge of an upper waveguide layer of the monolithic integrated multi-segment cascade optical frequency comb, and a length of the optogalvanic distribution grating accounts for one-third to four-fifth of an overall length of the first reverse bias absorption area; the optogalvanic distribution grate includes a narrow spectral optical compression grating.

Preferably, the first gain cavity length extender and the second gain cavity length extender both include multiple disk-shaped cavities coupled to each other. At the same time, this gain cavity length extender with coupled multi-disk structure also serves as a splitter and an optical feedbacker.

Preferably, each the disk-shaped cavity has a diameter of 5-100 μm, each the disk-shaped cavity is etched out with a disk height of 0.5-10 μm, and a shortest distance between outer edges of two disk-shaped cavities is −20 μm-200 nm;

the semiconductor optical amplifier has a total length of 400-5000 μm, a ridge waveguide width of 2-30 μm and a ridge waveguide height of 0.5-6 μm;

in the first, second, third and fourth electrical isolation grooves, a groove width is 5-20 μm, an etching depth is 0.3-0.7 μm, and a length is 300-500 μm.

Preferably, the first gain cavity length extender and the second gain cavity length extender both include multiple ring-shaped cavities coupled to each other. At the same time, this gain cavity length extender with coupled multi-ring structure also serves as a splitter and an optical feedbacker.

Preferably, an outer diameter of each the ring-shaped cavity is 5-100 μm, a height of a ridge waveguide formed by etching of each the ring-shaped cavity is 0.5-10 μm, a ring width of each the ring-shaped cavity is 100 nm-20 μm, and a shortest distance between outer edges of two neighboring ring-shaped cavities is −20 μm-200 nm;
the semiconductor optical amplifier has a total length of 400-5000 μm, a ridge waveguide width of 2-30 μm and a ridge waveguide height of 0.5-6 μm;
in the first, second, third and fourth electrical isolation grooves, a groove width is 10-20 μm, an etching depth is 0.3-0.7 μm, and a length is 300-500 μm.

Secondly, the present disclosure also provides a monolithic integrated multi-segment cascade optical frequency comb chip, and the monolithic integrated multi-segment cascade optical frequency comb chip includes the monolithic integrated multi-segment cascade optical frequency comb as described in any one of the aforementioned items of the present disclosure.

Preferably, the monolithic integrated multi-segment cascade optical frequency comb chip includes an integrated structure formed on an epitaxial wafer of a semiconductor laser, the epitaxial wafer of the semiconductor laser is sequentially from bottom to top: a substrate, a transition layer, a lower limiting layer, a lower waveguide layer, an active layer, an upper waveguide layer, an upper limiting layer, and a highly doped layer.

Preferably, the active layer includes a single quantum well active layer, a multiple quantum well active layer, a quantum dot active layer, or an active layer of a combined structure of quantum dots and quantum wells.

Preferably, the active layer further includes a lower electrode prepared below the substrate, and an upper electrode prepared above the highly doped layer. For the bipolar device, the electrons are injected from the lower electrode and the electrons flow out from the upper electrode. For the unipolar device, electrons are injected from the upper electrode and the electrons flow out from the lower electrode.

As can be seen from the above technical solutions, compared with the prior art, the present disclosure provides a monolithic integrated multi-segment cascade optical frequency comb and its chip, which have the following beneficial effects:
By proposing a monolithic integrated multi-segment cascade optical frequency comb and its chip, the present disclosure is able to realize an optical frequency comb integrating small size, high efficiency, tunable feature, fundamental mode, high power, narrow pulse width and flexible controllability, which is of great practical significance for the application and research of optical comb chip integration.

### DESCRIPTION OF THE ACCOMPANYING DRAWINGS

In order to more clearly illustrate the technical solutions in the embodiments or prior art of the present disclosure, the accompanying drawings to be used in the description of the embodiments or prior art will be briefly introduced below, and it will be obvious that the accompanying drawings in the following description are only embodiments of the present disclosure, and for ordinary technical personnel in this field, other drawings can be obtained based on the provided drawings without creative labor.

FIG. 1 shows a schematic diagram of the structure of a monolithic integrated multi-segment cascade optical frequency comb with a dual disk structure provided by an embodiment of the present disclosure;

FIG. 2 shows a schematic diagram of the structure of a monolithic integrated multi-segment cascade optical frequency comb of a dual ring structure provided by an embodiment of the present disclosure;

FIG. 3 shows a schematic diagram of the end face structure of a monolithic integrated multi-segment cascade optical frequency comb chip provided by an embodiment of the present disclosure;

FIG. 4 shows a graph of the spectral output characteristics of an epitaxial wafer for a GaSb-based˜2 μm semiconductor laser provided by an embodiment of the present disclosure;

FIG. 5 shows a graph of the spectral output characteristics of an epitaxial wafer of an InP-based 1653 nm semiconductor laser provided by an embodiment of the present disclosure.

In the figures, 001—first reverse bias absorption segment integrated with optogalvanic distribution grating; 002—first gain cavity length extender segment; 003—semiconductor optical amplifier segment; 004—second gain cavity length extender segment; 005—second reverse bias absorption segment; each segment is connected to each other by electrical insulation isolation groove; 1—substrate 1; 2—transition layer; 3—lower limiting layer; 4—lower waveguide layer; 5—active layer; 6—upper waveguide layer; 7—upper limiting layer; 8—highly doped layer; 01—lower electrode; 02—upper electrode; 03—SiO₂ film layer.

### DETAILED DESCRIPTION OF THE EMBODIMENTS

The technical solutions in the embodiments of the present disclosure will be clearly and completely described below in conjunction with the accompanying drawings in the embodiments of the present disclosure, and it is clear that the described embodiments are only a part of the embodiments of the present disclosure and not all of the embodiments. Based on the embodiments in the present disclosure, all other embodiments obtained by a person of ordinary skill in the art without making creative labor are within the scope of protection of the present disclosure.

In the description of the present application, it is to be understood that the terms “center”, “longitudinal”, “transverse”, “up”, “down”, “front”, “back”, “left”, “right”, “vertical”, “horizontal”, “top”, “bottom”, “inside”, “outside”, etc. indicate orientations or positional relationships that are based on those shown in the accompanying drawings, and are intended only to facilitate the description of the present application and to simplify the description, and are not intended to indicate or imply that the device or element referred to must have a specific orientation, be constructed and operated in a specific orientation, and therefore is not to be construed as a limitation of the scope of protection of the present application. Furthermore, the terms “first”, “second”, etc. are used only for descriptive purposes and are not to be understood as indicating or implying relative importance or implicitly specifying the number of technical features indicated. Thus, a feature defined with “first”, “second”, etc. may expressly or implicitly include one or more such features. In the description of the present application, unless otherwise specified, “multiple” means two or more.

### Embodiment 1

The embodiment of the present disclosure provides a monolithic integrated multi-segment cascade optical frequency comb, including, a first semiconductor passive mode-locking laser, a semiconductor optical amplifier, and a second semiconductor passive mode-locking laser; wherein, the first semiconductor passive mode-locking laser includes a first reverse bias absorption area integrated with a optogalvanic distribution grating and a first gain cavity length extender; the first reverse bias absorption area is connected to one end of the first gain cavity length extender through a first electrical isolation groove, and the other end of the first gain cavity length extender is connected to the semiconductor optical amplifier through a second electrical isolation groove; the second semiconductor passive mode-locking laser includes a second gain cavity length extender and a second reverse bias absorption area, one end of the second gain cavity length extender is connected to the semiconductor optical amplifier through a third electrical isolation groove, and the other end of the second gain cavity length extender is connected to the second reverse bias absorption area through a fourth electrical isolation groove.

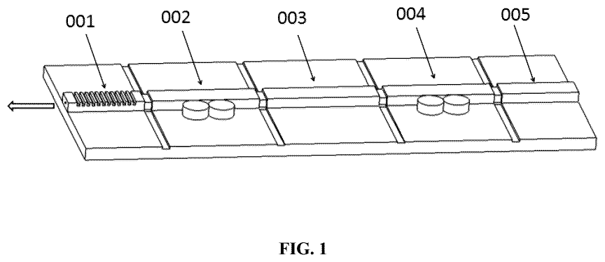

As shown in FIG. 1, in this embodiment, the first semiconductor passive mode-locking laser MLL₁ is composed of a optogalvanic distribution grating OG (SA₁+OG segment 001) integrated in the first reverse bias absorption area SA₁, and a first gain cavity length extender segment 002 integrated in the gain area of the MLL₁, and specifically, in the first semiconductor passive mode-locking laser MLL₁, the optogalvanic distribution grating OG may adopt a spectral light compression grating structure; the second semiconductor passive mode-locking laser MLL₂ is composed of a second gain cavity length extender segment 004 and a second reverse bias absorption segment 005, and the difference from the first semiconductor passive mode-locking laser MLL₁ is that the reverse bias area of the second semiconductor passive mode-locking laser MLL₂ does not have a grating structure; the first semiconductor passive mode-locking laser MLL₁ and the second semiconductor passive mode-locking laser MLL₂ are directly connected to each other by a semiconductor optical amplifier (SOA) segment 003 through electrical isolation grooves.

The first gain cavity length extender segment 002 and the second gain cavity length extender segment 004 in this embodiment both include two disk-shaped cavities coupled to each other.

In the embodiment 1, the monolithic integrated multi-segment cascade optical frequency comb includes five functional segments. Although the pre-chirp management amplification (PCMA) technique can utilize the grating for precise control of the amount of pulse negative chirp, the spatial structure of the grating may damage the all-optical waveguide structure, which is not conducive to the stability of the amplification system. In contrast, the integrated multi-segment cascade optical frequency comb structure based on the semiconductor laser epitaxial material platform proposed in this embodiment does not have such a problem.

For SA₁+OG segment 001, the optogalvanic grating structure is integrated on the waveguide in the reverse bias area, the optogalvanic grating is used to generate optogalvanic through the reverse bias of the operating voltage, and the optogalvanic is distributed through the grating electrodes to form a refractive index periodic structure to realize the spectral linewidth compression and wavelength control of the transmitted light in the waveguide, and in the present embodiment, the grating etching cutoff position is more than two-thirds of the thickness of the upper waveguide, and the whole grating length accounts for two-thirds of the length of the first reverse bias area;

The first gain cavity length extender segment 002 is a controllable modulation feedback area for light, and forms a multi-cavity structure with the other second gain cavity length extender segment 004 and two end cavity surfaces of the optical frequency comb OFC, the two segments internally enrich the “comb teeth” of the optical comb by means of the generated Kerr effect and the multi-periodicity of light in the two dual disks, and the two dual disks also have the function of adjusting and controlling the line width; the semiconductor optical amplifier segment 003 is a straight ridge waveguide structure current forward drive, plays the role of bidirectional optical gain amplification and spectral broadening; the second reverse bias absorption segment 005 is the reverse bias area at the other end of the optical frequency comb OFC, which may enables homogenous or differential control of structure and modulation with the other end.

In this embodiment, the monolithic integrated multi-segment cascade optical frequency comb combines chirped pulse amplification (CPA), waveguide dissipation, four-wave mixing (FWM), the Kerr effect, and passive mode-locking techniques in its operation. Multi-segment cascading is realized through a semiconductor laser epitaxial structure platform. The optical pulse generated by the second semiconductor passive mode-locking laser MLL₂ partially passes through the semiconductor optical amplifier SOA to realize pulse broadening, and then passes through the reverse bias absorption area SA₁ of the first semiconductor passive mode-locking laser MLL₁ with optogalvanic distribution grating structure to realize optical pulse compression, then the feedback light passes through the dual-disk structure of the first gain cavity length extender DD₁ and the second gain cavity length extender DD₂ to realize dense multi “comb teeth”, and through the mode locking of the mode-locking segment, the output of single-chip optical comb light source is finally realized.

In this embodiment, the segments are separated by electrical isolation strips, which provides higher freedom, rich controllability and diverse selectivity for the output of the optical comb. The optogalvanic distribution grating structure of the reverse bias saturation area of the first semiconductor passive mode-locking laser MLL₁ can play the role of wavelength tuning through electrical injection in addition to providing pulse compression; the gain cavity length extender carries out optical gain as well as cavity length equivalence extension through the two mutually coupled disk cavities to reduce the waveguide loss and regulate and control the spacing of the optical comb teeth; the SOA segment of the semiconductor optical amplifier plays the role of pulse broadening and optical intensity amplification, which is equivalent to the broadening grating in the CPA technology; the integration of two passive mode-locking lasers can further enhance the regulation of the density of the optical comb teeth to regulate the optical comb. The whole structure is conducive to the realization of a wide wavelength range of optical modulation output.

Referring to FIG. 1, in this embodiment, the total length of the first semiconductor passive mode-locking laser MLL₁ (the sum of the SA₁+OG segment 001 and the first gain cavity length extender segment 002) is 1500 μm, the ridge waveguide width is 3 μm, and the ridge waveguide height is 3 μm, of which the length of the SA₁+OG segment 001 is 100 μm, and the optogalvanic grating OG period and its constants are designed in accordance with the modulated wavelength, according to the center wavelength to meet the following Bragg equation: λBragg=2 nΛ, where n is the refractive index, Λ is the grating period. Because the parameters n and A are affected by temperature and strain, Bragg reflected light center wavelength will also change with the temperature or strain, or both, the etching cutoff position of the grating is more than two-thirds of the thickness of the upper waveguide, and the whole length of the grating accounts for two-thirds of the length of the first reverse bias area; the ridge waveguide length in the first gain cavity length extender segment 002 is 2000 μm, the ridge waveguide width is 3 μm; the diameter of each disk-shaped cavity is 10 μm, the height of each disk-shaped cavity surface formed through the etching process is 3 μm, the outer edges of the two disks are 200 nm apart; the total length of the semiconductor optical amplifier segment 003 is 3000 μm, the ridge waveguide width is 3 μm, and the ridge waveguide height is 3 μm; the total length of the second passive mode-locking semiconductor laser MLL₂ (the sum of the second gain cavity length extender segment 004 and the second reverse bias absorption segment 005) is 2000 μm, the ridge waveguide width is 3 μm, the ridge waveguide height is 3 μm, of which the length of the second reverse bias absorption segment 005 is 100 μm; in the second gain cavity length extender segment 004, the diameter of each disk-shaped cavity is 10 μm, the height of each disk-shaped cavity surface formed through the etching process is 3 μm, and the outer edges of the two disks are 200 nm apart.

Parameters of the electrical isolation groove: the groove width is 10 μm, the etching depth is 0.5 μm, and length is 500 μm.

### Embodiment 2

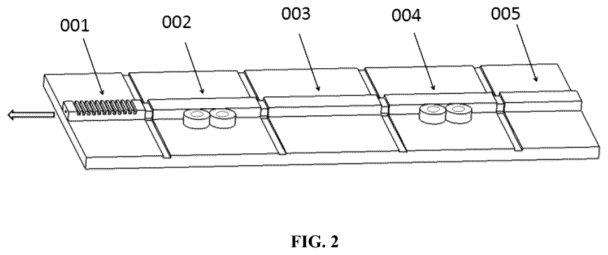

As shown in FIG. 2, the difference between embodiment 2 and embodiment 1 is that the first gain cavity length extender segment 002 and the second gain cavity length extender segment 004 both include two ring-shaped cavities coupled to each other.

Referring to FIG. 2, in this embodiment, the total length of the first semiconductor passive mode-locking laser MLL₁ (the sum of the SA₁+OG segment 001 and the first gain cavity length extender segment 002) is 1500 μm, the ridge waveguide width is 5 μm, and the ridge waveguide height is 2 μm, of which the length of the SA₁+OG segment 001 is 300 μm, and the optogalvanic grating OG period and its constants are designed in accordance with the modulated wavelength, according to the center wavelength to meet the following Bragg equation: λBragg=2 nΛ, where n is the refractive index, Λ is the grating period. Because the parameters n and A are affected by temperature and strain, Bragg reflected light center wavelength will also change with the temperature or strain, or both, the etching cutoff position of the grating is more than one-half of the thickness of the upper waveguide, and the whole length of the grating accounts for one-third to four-fifths of the length of the first reverse bias area; the ridge waveguide length in the first gain cavity length extender segment 002 is 1800 μm, the ridge waveguide width is 5 μm; the diameter of each ring-shaped cavity DR₁ is 30 μm, the width of the ring is 2 μm, the ridge structure of the ring waveguide formed by etching process for each ring-shaped cavity DR₁ has a height of 2 μm, the outer edges of the two rings are −2 μm apart; the total length of the semiconductor optical amplifier segment 003 is 2000 μm, the ridge waveguide width is 5 μm, and the ridge waveguide height is 2 μm; the total length of the second passive mode-locking semiconductor laser MLL₂ (the sum of the second gain cavity length extender segment 004 and the second reverse bias absorption segment 005) is 2000 μm, the ridge waveguide width is 5 μm, the ridge waveguide height is 2 μm, of which the length of the second reverse bias absorption segment 005 is 200 μm.

Parameters of the electrical isolation groove: the groove width is 10 μm, the etching depth is 0.7 μm, and length is 400 μm.

### Embodiment 3

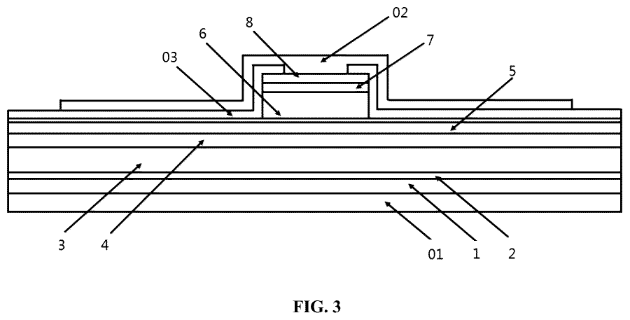

This embodiment discloses, on the basis of embodiment 1 or embodiment 2, a chip including any of the above monolithic integrated multi-segment cascade optical frequency combs. As shown in FIG. 3, the epitaxial structure of the monolithic integrated multi-segment cascade optical frequency comb chip is sequentially from bottom to top: a substrate 1, a transition layer 2, a lower limiting layer 3, a lower waveguide layer 4, an active layer 5, an upper waveguide layer 6, an upper limiting layer 7, and a highly doped layer 8.

The active layer 5 in this embodiment may specifically be: a single quantum well active layer, a multiple quantum well active layer, a quantum dot active layer, or an active layer of a combined structure of quantum dots and quantum wells.

As shown in FIG. 3, the monolithic integrated multi-segment cascade optical frequency comb chip further includes a lower electrode 01 prepared below the substrate 1, and an upper electrode 02 prepared above the highly doped layer 8. In addition, a SiO₂ film layer 03 is prepared between the upper electrode 02 and the upper waveguide layer 6.

Usually, the lower electrode is an N-plane electrode and the upper electrode is a P-plane electrode.

In this embodiment, the two ends of the chip output light may be plated with a high reflective film and a transmittance-enhancing film, respectively.

In this embodiment, the integrated multi-segment cascade optical frequency comb chip suppresses thermal refractive index noise through a dual passive mode-locking semiconductor laser structure to obtain the optical comb output, realizing a single-chip integrated optical comb with active and passive integration. The structures include, in order, a first reverse bias absorption area SA₁ integrated with an optogalvanic distribution grating OG, a first gain cavity length extender (dual-disk DD₁/dual-ring DR₁ modulation area structure), a semiconductor optical amplifier area structure SOA, a second gain cavity length extender (dual disk DD₂/dual ring DR₂ modulation area structure), and a second reverse bias absorption area SA₂ structure, each of which is connected by an electrical isolation groove strip structure.

### Embodiment 4

This embodiment discloses a GaSb-based˜2 μm semiconductor laser epitaxial wafer, with the materials and dimensions of the layers in the epitaxial structure as shown in Table 1.

TABLE 1

| Layer | Material | Thickness (nm) |
|---|---|---|
| Highly doped layer | GaSb | 130 |
| Upper limiting layer | Al_{0.5}GaAsSb | 2000 |
| Upper waveguide | Al_{0.25}GaAsSb | 270 |
| layer | | |
| Active layer | In_{0.2}Ga_{0.8}Sb | 10 |
| Lower waveguide | Al_{0.25}GaAsSb | 270 |
| layer | | |
| Lower limiting layer | Al_{0.5}GaAsSb | 2000 |
| Transition layer | GaSb | 500 |
| Substrate | GaSb | 660 μm |

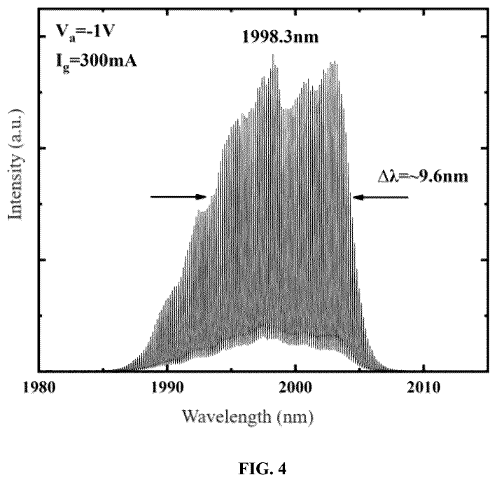

In this embodiment, the gain cavity length extender adopts two mutually coupled disk-shaped cavities, and the size specification of each segment is as followings: the first reverse bias absorption area L_{SA1}=302.08 μm, the waveguide width is 2 μm; the grating etching depth is 2200 nm, the whole grating length is 230 μm; the length of a straight waveguide coupled to a disk cavity in the first gain length extender is L_{DD1}=3171.8 μm, the radius of a single disk-shaped cavity R=20 μm, and the waveguide width is 2 μm; the semiconductor optical amplifier segment L_{SOA}=800 μm, the waveguide width is 2 μm; the second reverse bias absorption area L_{SA2}=302.08 μm, the waveguide width is 2 μm, the length of a straight waveguide coupled to a disk cavity in the second gain length extender is L_{DD2}-3171.8 μm, the radius of a single disk-shaped cavity R=20 μm, and the waveguide width is 2 μm; the distance between the two disks of the first gain length extender and the second gain length extender is 50 nm, and the waveguide width is 2 μm; the ridge height formed by an etching process of each disk-shaped cavity and ridge waveguide is 3 μm; the distance between the two disks and the straight waveguide is 50 nm; the width of the electrical isolation groove is 10 μm, the etching depth is 0.5 μm, and the length of the electrical isolation groove is 500 μm; and at room temperature, under the condition that the reverse bias voltage Vₐ of the reverse bias absorption area is −1V and the current I_{g} is 300 mA, the spectral output characteristic diagram outputted by this embodiment is shown in FIG. 4.

In this embodiment, the reverse bias voltage applied to the first reverse bias absorption area and the reverse bias voltage applied to the second reverse bias absorption area are −1 V. In other embodiments, different voltage values may be adopted for the reverse bias voltage of the first reverse bias absorption area and the reverse bias voltage of the second reverse bias absorption area.

### Embodiment 5

This embodiment discloses an InP-based 1653 nm semiconductor laser epitaxial wafer, with the materials and dimensions of each layer in the epitaxial structure as shown in Table 2.

TABLE 2

| | | Thicknesses |
|---|---|---|
| Level | Material | (nm) |
| Highly doped layer | In_{0.53}Ga_{0.47}As | 180 |
| | In_{0.62}Ga_{0.38}As_{0.82}P_{0.18} | 25 |
| | In_{0.72}Ga_{0.28}As_{0.60}P_{0.40} | 25 |
| limiting layer | InP | 1700 |
| Upper waveguide | In_{0.72}Ga_{0.28}As_{0.60}P_{0.40} | 20 |
| layer | Grating | |
| | InP | 40 |
| | In_{0.85}Ga_{0.15}As_{0.32}P_{0.68} | 10 |
| | Etch stop | |
| | InP | 50 |
| | In_{0.53}Al_{0.29}Ga_{0.18}As to | 100 |
| | In_{0.52}Al_{0.48}As GRIN SCH | |
| Active layer | In_{0.49}Al_{0.20}Ga_{0.31}As Barrier | 10 |
| | In_{0.77}Al_{0.01}Ga_{0.22}As Well | 5.5 |
| | In_{0.49}Al_{0.20}Ga_{0.31}As Barrier | 10 |
| Hybrid layer of lower | In_{0.52}Al_{0.48}As to | 100 |
| limiting and lower | In_{0.53}Al_{0.29}Ga_{0.18}As GRIN SCH | |
| waveguide | | |
| Transition layer | InP buff | 500 |
| Substrate | InP Sub | 350 μm |

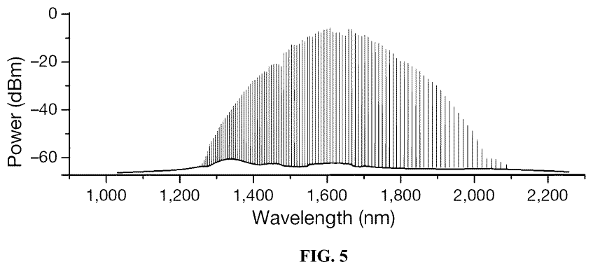

In this embodiment, the gain cavity length extender adopts two mutually coupled ring-shaped cavities, and the size specification of each segment is as followings: the first reverse bias absorption area L_{SA1}-300 μm; the whole grating length is 200 μm; the length of straight waveguide coupled to the ring-shaped cavity in the first gain cavity length extender L_{DD1}=3000 μm, the radius of the single ring-shaped cavity R=25 μm (half of the outer diameter of the ring-shaped cavity), and the waveguide width is 3 μm; the semiconductor optical amplifier segment L_{SOA}=5000 μm, the waveguide width is 3 μm; the second reverse bias absorption area L_{SA2}=300 μm, the waveguide width is 3 μm; the length of straight waveguide coupled to the ring-shaped cavity in the first gain cavity length extender L_{DD2}=3000 μm, the waveguide width is 3 μm; the distance between the two rings in the first gain length extender and the second gain length extender is 50 nm, the waveguide width is 3 μm, the etching depth of waveguide of each ring-shaped cavity is 2 μm; the distance between the two rings and the straight waveguide is 50 nm; the width of the electrical isolation groove is 10 μm, the etching depth is 0.6 μm, and the length of the electrical isolation groove is 500 μm; the spectral output characteristic diagram outputted by this embodiment is shown in FIG. 5.

Each segment in the monolithic integrated multi-segment cascade optical frequency comb chip in the embodiments of the present disclosure is further described again below.

1) First Reverse Bias Absorption Area SA₁ Integrated with Optogalvanic Distribution Grating OG

In the first reverse bias absorption area SA₁, the length of the reverse bias area determines the peak intensity and spectral width of the optical pulse. A grating structure for optogalvanic modulation is integrated on the straight ridge of the area, and the refractive index of the current gradient caused by the distribution of the intensity of the optogalvanic generated through the area varies in a grating cycle, and the method of compressing the optical pulse using a specific structural grating realizes the compression and modulation of the spectral width.

### 2) First Gain Cavity Length Extender (Dual Disk DD₁/Dual Ring DR1 Modulation Area Structure)

The embodiment of the disclosure breaks through the limitation of the traditional single ring or disk, and makes full use of the dual disk/ring modulation area to play the role of optical feedback, optical modulation and optical cavity extension. The nonlinear proportional modulation of light from the waveguide area is realized through the multi-order or high-order nonlinear effects of the dual disk/ring structure. The disk structure can obtain higher light transfer efficiency, and the ring structure can realize light modulation more easily. In addition to its own parameters (radius, curvature) to determine the role of the dual disk/ring, its coupling to the waveguide determines the modulation efficiency and effectiveness of the double disk/ring.

### 3) Semiconductor Optical Amplifier Area Structure SOA

Optical gain amplifier area can realize both the gain amplification of light, as well as the spectral broadening of transmitted light, and its structural parameters are directly related to the optical amplification capability. For the convenience of integration, the width can be determined by comprehensively considering the waveguide parameters of other segments under high-power single-mode operating conditions. At the same time, specific etching parameters and sidewall smoothness are required. Excessive etching depth of the waveguide is not conducive to stable optical amplification, as it increases waveguide loss during light propagation, and moderate etching depth and improved sidewall smoothness are beneficial for achieving high gain.

4) Second Gain Cavity Length Extender (Dual Disk DD₂/Dual Ring DR₂ Modulation Area Structure)

In the second gain cavity length extender, the dual disk/ring modulation area, in addition to having the same structure and function as the dual disk/ring of the first gain cavity length extender mentioned above, can also realize the multi-functionality of the OFC chip through the electrical modulation of the area, combined with the above first gain cavity length extender, by electrical injection of two dual disk/ring vernier effects, splitting ratio, gain amplification, interlocking and self-locking, which includes the output specifications such as the four-wave mixing (FWM) degree, wavelength position, linewidth, width of the OFC, and even soliton characteristics. The study of its position and structural parameters helps to realize the broad spectrum, high power and stable output characteristics of the optical comb.

### 5) Second Reverse Bias Absorption Area SA₂ Structure

In the second reverse bias absorption area SA₂, no optogalvanic distribution grating structure is integrated in this segment of the reverse bias area. This area provides phase-locked, feedback light and broadened OFC output through reverse current biasing and optical feedback from the immediately adjacent cavity surface, and is part of the integrated passive mode-locking semiconductor mode-locking laser. Its length determines the optical pulse width, intensity and spectral width of the OFC of the feedback light. Therefore, its relevant structural parameters are required to match the output characteristics while ensuring high-power, single-mode operation.

### Electrical Isolation Strip Structure Between Segments

Each segment in the integrated multi-segment cascade optical frequency comb chip of this embodiment has a different function, and the reverse bias and forward bias have significant differences. In order to avoid the influence of the mutual electrical characteristics of the neighboring segments, it is necessary to have sufficient electrical isolation width and etching depth between the segments. If the isolation strip is too wide, the internal loss of light in the isolation strip will be increased, the light extraction efficiency will be affected, and the output characteristics of the chip will be reduced; if the isolation strip is too narrow, the two adjacent segments will easily form mutual interference, and the functionality of each other will be affected; too deep an isolation strip may weaken the light transmittance, increase the internal loss, and too shallow an isolation strip may lead to electrical crosstalk in adjacent areas, thereby affecting the output characteristics of the device.

### OFC Chip Process Preparation

The monolithic integrated multi-segment cascade optical frequency comb chip in this embodiment can be studied using a combination of wet and dry etching processes. In the structure, the coupling method of grating, dual disk/ring and straight ridge waveguide is involved. The prepared structure and morphology directly determine the optical output characteristics of the device. Dry etching can realize high-precision control, especially the control of the coupling distance and coupling mode between gratings, double disk/ring, and straight ridge waveguides, which is an important link to determine the optical output characteristics of OFC. Wet etching has a smooth surface topography, which is conducive to the formation of low-loss interfaces. The combination of wet and dry methods can realize excellent device structures.

Segmented process preparation can achieve optimal preparation of the structure of each segment and avoid the impact of device performance caused by the variability of the process parameters among the segments.

The dual disk/ring used in the gain cavity length extender in this embodiment has multiple functions. First, it has the function as a cavity surface. It feedbacks the light from the end of the cavity surface to form a mode-locked passive mode-locking semiconductor laser structure with the reverse bias area near the end of the cavity surface. The optical comb teeth of each frequency of the optical comb are formed by the 0 to n-th optical range difference of different components of light rotating in the dual disk/ring. Two passive mode-locking semiconductor laser structures with dual disks/ring form abundant optical teeth through cavity surface feedback at the output.

Secondly, together with the optical amplification area (SOA), it serves as a gain area. Intense light gain amplification is formed by means of intracavity oscillation between the two dual disks/rings formed to provide sufficiently high light intensity and spectral broadening for the mode-locking area. Thirdly, the internal optical nonlinear effect is induced by an external intense light pulse. When the external light pulse is intense enough, the dual disk/ring itself can cause nonlinear effects within itself by the external intense light pulse, resulting in four-wave mixing and Kerr effect, which is equivalent to the active micro disk/ring structure. Each dual disk/ring can form bidirectional feedback. The nonlinear effects of the disk/ring area are closely related to the light intensity in the external straight waveguide area and the structure within the active waveguide of the disk/ring. The parameters of the disk/ring affect its own optical loss.

Finally, the respective radii of the dual disk/ring determine the tunable bandwidth and the comb spacing. Comb teeth selection and positional adjustment are realized by the vernier effect. A Ti/Au film is prepared as an external modulation electrode on the straight ridged waveguide coupled to the dual disk/ring to replace the simple Al/TiN heating electrode, which can control the optical feedback of the dual disk/ring resonator and also provide a certain optical gain to reduce the optical loss. With two dual disks/rings, the best modulation effect can be achieved for the light in the waveguide. In addition, the coupling mode of the dual disk/ring to the straight waveguide and the related parameters affect the output optical comb performance, which may have a large impact on optical feedback efficiency and tunable wavelength bandwidth.

In the multi-segment structured OFC light source chip, the influence of high-order Kerr effect and FWM in each segment has a close relationship with the structural parameters of each segment. Small-size structural parameters, high light intensity, and large gain characteristics will certainly be more likely to cause optical nonlinear effects and FWMF inside the device, and these effects and principles are utilized to generate meaningful device output characteristics.

The entire waveguide of the optical comb chip in this embodiment is on a uniform material epitaxial consistent platform with an uninterrupted structure, and the chip structure and process do not disrupt the integrity of the platform. At the same time, the two dual disk/ring structures can be cavity surfaces of each other, with compatibilities and selectivities to various lights. Therefore, the stability of the amplification system is not affected.

Compared with the traditional passive structure OFC with only single-ring microcavity and optical fiber ring structure, the multi-segment cascade integrated active controllable OFC light source chip structure provided in the present disclosure has the advantages as followings: it has small system volume and is able to realize the OFC chip control with the integration of active and passive parts; the system has good working stability, and does not require external complex and special temperature control conditions; the system has a wide application wavelength range, and the line width and the wavelength range can be adjusted to some extent; it has a relatively strong light output capability, and has a relatively high peak pulse power; the preparation process is integrated with a semiconductor laser preparation process, which is easy to implement and suitable for batch production, so as to reduce costs; the segments are independently controlled, and a structural basis is established for realizing a fundamental mode, a high power and a wide spectral output of the integrated device as a whole. There are significant advantages over the single-ring passive microcavity OFC structure.

The embodiments in this description are described in a progressive manner, each embodiment focuses on a difference from other embodiments, and reference may be made to each other for the same or similar parts of the embodiments. Since the device disclosed in the embodiment corresponds to the method disclosed in the embodiment, the description thereof is relatively simple, and for the relevant parts, reference can be made to the description of the method.

The above description of the disclosed embodiments enables a person skilled in the art to realize or use the present disclosure. Various modifications to these embodiments will be apparent to those skilled in the art, and the general principles defined herein may be realized in other embodiments without departing from the spirit or scope of the present disclosure. Accordingly, the present disclosure will not be limited to these embodiments shown herein, but will be subject to the broadest scope consistent with the principles and novel features disclosed herein.

What is claimed is:

1. A monolithic integrated multi-segment cascade optical frequency comb, characterized in that it comprises:
a first semiconductor passive mode-locking laser, a semiconductor optical amplifier, and a second semiconductor passive mode-locking laser;
wherein, said first semiconductor passive mode-locking laser comprises a first reverse bias absorption area integrated with an optogalvanic distribution grating and a first gain cavity length extender; said first reverse bias absorption area is connected to one end of said first gain cavity length extender through a first electrical isolation groove, and the other end of said first gain cavity length extender is connected to said semiconductor optical amplifier through a second electrical isolation groove;
said second semiconductor passive mode-locking laser comprises a second gain cavity length extender and a second reverse bias absorption area, one end of said second gain cavity length extender is connected to said semiconductor optical amplifier through a third electrical isolation groove, and the other end of said second gain cavity length extender is connected to said second reverse bias absorption area through a fourth electrical isolation groove.

2. The monolithic integrated multi-segment cascade optical frequency comb according to claim 1, characterized in that an etching depth of said optogalvanic distribution grating is one-hundredth to one-half of a thickness downwards starting from an upper edge of an upper waveguide layer of the monolithic integrated multi-segment cascade optical frequency comb, and a length of said optogalvanic distribution grating accounts for one-third to four-fifth of an overall length of the first reverse bias absorption area; said optogalvanic distribution grate comprises a narrow spectral optical compression grating.

3. The monolithic integrated multi-segment cascade optical frequency comb according to claim 1, characterized in that said first gain cavity length extender and said second gain cavity length extender both comprise a plurality of disk-shaped cavities coupled to each other.

4. The monolithic integrated multi-segment cascade optical frequency comb according to claim 3, characterized in that each said disk-shaped cavity has a diameter of 5-100 μm, each said disk-shaped cavity is etched out with a disk height of 0.5-10 μm, and a shortest distance between outer edges of two disk-shaped cavities is −20 μm-200 nm;
said semiconductor optical amplifier has a total length of 400-5000 μm, a ridge waveguide width of 2-30 μm and a ridge waveguide height of 0.5-6 μm;
in said first, second, third and fourth electrical isolation grooves, a groove width is 5-20 μm, an etching depth is 0.3-0.7 μm, and a length is 300-500 μm.

5. The monolithic integrated multi-segment cascade optical frequency comb according to claim 1, characterized in that said first gain cavity length extender and said second gain cavity length extender both comprise a plurality of ring-shaped cavities coupled to each other.

6. The monolithic integrated multi-segment cascade optical frequency comb according to claim 5, characterized in that an outer diameter of each said ring-shaped cavity is 5-100 μm, a height of a ridge waveguide formed by etching of each said ring-shaped cavity is 0.5-10 μm, a ring width of each said ring-shaped cavity is 100 nm-20 μm, and a shortest distance between outer edges of two neighboring ring-shaped cavities is −20 μm-200 nm;
said semiconductor optical amplifier has a total length of 400-5000 μm, a ridge waveguide width of 2-30 μm and a ridge waveguide height of 0.5-6 μm;
in said first, second, third and fourth electrical isolation grooves, a groove width is 10-20 μm, an etching depth is 0.3-0.7 μm, and a length is 300-500 μm.

7. A monolithic integrated multi-segment cascade optical frequency comb chip, characterized in that it comprises the monolithic integrated multi-segment cascade optical frequency comb described in claim 1.

8. The monolithic integrated multi-segment cascade optical frequency comb chip according to claim 7, characterized in that said monolithic integrated multi-segment cascade optical frequency comb chip comprises an integrated structure formed on an epitaxial wafer of a semiconductor laser, said epitaxial wafer of the semiconductor laser is sequentially from bottom to top: a substrate, a transition layer, a lower limiting layer, a lower waveguide layer, an active layer, an upper waveguide layer, an upper limiting layer, and a highly doped layer.

9. The monolithic integrated multi-segment cascade optical frequency comb chip according to claim 8, characterized in that said active layer comprises a single quantum well active layer, a multiple quantum well active layer, a quantum dot active layer, or an active layer of a combined structure of quantum dots and quantum wells.

10. The monolithic integrated multi-segment cascade optical frequency comb chip according to claim 8, characterized in that it further comprises a lower electrode prepared below the substrate, and an upper electrode prepared above the highly doped layer.
